(19) United States
(12) Patent Application Publication
(10) Pub. No.: US 2013/0038173 A1
(43) Pub. Date: Feb. 14, 2013

(54) MULTI DEGREE-OF-FREEDOM PIEZOELECTRIC MICRO-ACTUATOR WITH AN ENERGY EFFICIENT ISOLATION STRUCTURE

(71) Applicant: Geoffrey William Rogers, Fitzroy (AU)

(72) Inventor: Geoffrey William Rogers, Fitzroy (AU)

(73) Assignee: Intellmedical Technologies PTY Ltd c/o MGI Melbourne, Melbourne (AU)

(21) Appl. No.: 13/580,716

(22) PCT Filed: Feb. 28, 2011
(86) PCT No.: PCT/AU11/00222

§ 371 Date: Oct. 9, 2012

(30) Foreign Application Priority Data
Feb. 28, 2010 (AU) 2010900849

(51) Int. Cl. H01L 41/04; H01L 41/047

(52) U.S. Cl. 310/326; 310/366; 310/328

(57) ABSTRACT

A multi-DOF piezoelectric actuator that may be constructed with sizes of about or less than one millimetre. The multi-DOF piezoelectric actuator is capable of generating motion of a rotor element or slider element, about or in, each of the three fundamental axes of three dimensional space. The actuator can comprise a piezoelectric element (10) having one or more sidefaces, a first endface, and a second endface, wherein at least one or more sidefaces comprise a plurality of separate sideface electrodes (11) and at least one of the first or second endfaces comprise an endface electrode (12). A transducer element (30,40) and isolation structure (5) for use in a piezoelectric actuator are also described.

### FIELD OF THE INVENTION

The present application concerns a piezoelectric actuator or micro-motor capable. of generating multi-degree-of-freedom (DOF) motion, with the actuator or motor having potential overall dimensions of a few millimetres or below the order of millimetres, and a structure for the relatively, energy efficient mounting of such actuators.

### BACKGROUND

There is much need within the micro-robotic and micro-engineering fields for actuators with a volume of less than one cubic centimetre. The common electromagnetic actuator, which is presently used in most applications, is generally not suited to reduction in size below the order of centimetres as necessary for micro-scale applications. This is largely due to the fact that the actuation force of an electromagnetic actuator scales as a function of the actuator size to the fourth power. Piezoelectric ultrasonic actuators, on the other hand, exhibit a more favourable scaling characteristic than electromagnetic actuators, whereby the force scales as a function of the actuator size to the first power. Hence, piezoelectric actuators are more suited to reduction in size below the order of centimetres.

A piezoelectric actuator commonly Consists of a piezoelectric element that may have a transducer element mounted atop to amplify the output performance. A piezoelectric actuator using a transducer element was recently developed with a transducer outer diameter of 241 μm (see B. Watson, J. Friend & L. Yeo, J. Micromech. Microeng. 19 (2009)). This actuator has proven capable of producing single DOF rotation of a rotor. However, multi-DOF micro-actuators are required for many applications, such as for the actuation of a spherical robotic eye, and for hip and shoulder joints as well as being required in many micro-robotic and micro-engineering fields. Piezoelectric actuators having a transducer of about 7 mm have also, been developed. The previous methods used for electrically exciting such piezoelectric multi-DOF actuators are not well suited to reduction in size below the order of millimetres, due to inherent manufacturing and assembly difficulties.

Upon mounting a resonant actuator to another entity, such as a system or substrate, whereby the entity does not provide a sufficiently rigid mount, a significant portion of energy can be lost from the actuator and absorbed by the system or substrate (see W. Newell, Proceedings of the IEEE (1965)). This lowers the actuation efficiency and can be destructive to sensitive surrounding systems. To alleviate this, the actuator can be mounted to the system or substrate via an intermediary isolation structure. This isolation structure is designed such that it reflects energy lost from the mounting point of the actuator back to the actuator, rather than allowing it to transmit to the mount with the system or substrate. This can be achieved using a two-segment structure, whereby the two segments are required to have a substantial acoustic impedance mismatch. As the material stiffness is the factor that affects the acoustic impedance most significantly, all other things being constant, it is typically desirable that a stiff and a non-stiff material be selected for such a structure. The major shortfall in using such a structure is that typical non-stiff materials, such as polymers, have substantially large acoustic dissipation factors, which means much of the energy that the actuator transmits to this structure, when employing such a material, will be lost due to viscous effects. Additionally, whilst such isolation structures are available for thin film, primary wave actuators (see K. Lakin, K. McCarron & R. Rose, IEEE Ultrasonics Symposium (1995)), no such structures have been presented for bulk, secondary wave actuators.

Any discussion of documents, acts, materials, devices, articles or the like which has been included in the present specification is not to be taken as an admission that any or all of these matters form part of the prior art base or were common general knowledge in the field relevant to the present invention as it existed before the priority date of each claim of this application.

### SUMMARY

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

It is a desired feature of the present invention to provide a multi-DOF piezoelectric actuator or micro-motor that may be constructed with sizes of about or less than one millimetre. An additional desired feature of the present invention is to provide a relatively energy efficient isolation structure for use in a piezoelectric actuator, that additionally does not necessitate the use of high acoustic-absorptive materials. Example embodiments of the actuator and isolation structure are provided herein. However, the application of this actuator and isolation structure are not restricted to the herein examples.

In one aspect, there is provided a piezoelectric actuator capable of generating motion of a rotor element or slider element, about or in, each of the three fundamental axes of three dimensional space, the actuator comprising a piezoelectric element having a body having:

one or more sidefaces,

a first endface, and

a second endface;

wherein said at least one or more sidefaces comprise a plurality of separate sideface electrode(s) and at least one of the first or second endfaces comprises an endface electrode.

In one embodiment, the piezoelectric element has a longitudinal axis that is defined as the axis perpendicular to the plane(s) in which the endface electrode(s) resides, and passes through the geometrical centre of the piezoelectric element. The piezoelectric element can be understood to have transverse axes that are, perpendicular to this longitudinal axis and each other. While the piezoelectric element can have a range of forms, it can comprise a rectangular block or a cylinder.

In one embodiment, the piezoelectric element can have one, greater than one, at least four or only four sidefaces. Where there is more than one sideface, each of the sidefaces can comprise a sideface electrode. Where there is one sideface, multiple electrodes can be provided on said sideface. In one embodiment, the body of the actuator can have one sideface comprising four electrodes.

The electrodes can comprise an electrically conductive material. Examples of suitable electrodes include metal films, eg silver or gold film, electrically conductive paint or paste, eg silver paint.

In one embodiment, where there are four sideface, electrodes, the electrodes can be arranged such that they form two pairs, whereby the two sideface electrodes of a given pair are on opposing sidefaces of or locations on the piezoelectric element. In this embodiment, each electrode of a pair of sideface electrodes can be located at or about 180 degrees of rotation angle from the other, about the longitudinal axis of the piezoelectric element.

Preferably, the two pairs of opposing sideface electrodes of the piezoelectric element are located such that the two axes perpendicular to the planes in which the sideface electrodes reside are:

perpendicular to each other, and

perpendicular to the axis that is perpendicular to the plane(s) in which the endface electrode(s) resides (ie. the longitudinal axis of the element).

In accordance with this, if the longitudinal axis is considered as the z-axis, the sideface electrodes of the piezoelectric element can be located such that:

two are parallel to a y-z plane, and

two are parallel to a x-z plane.

The piezoelectric element can be formed of any suitable piezoelectric material, including a piezoelectric ceramic material. In one embodiment, the piezoelectric element can comprise a lead zirconate titanate (PZT) element. PZT can be commercially obtained from a range of suppliers, such as Fuji Ceramics Corporation (Japan).

The piezoelectric element can be polarised in the direction of the longitudinal axis.

The piezoelectric element can be actuated by inducing lateral and/or longitudinal vibration of the element.

Lateral vibration can be induced by applying an alternating current (AC) signal across a pair of opposing sideface electrodes, whereby—
one sideface electrode may be connected to a positive polarity AC signal, while the other is grounded, or
one sideface electrode may be connected to a positive polarity AC signal, while the other is connected to a negative polarity AC signal, such that the two signals are 180 degrees out of phase.

Longitudinal vibration can be induced by applying an AC signal to either of the pairs of opposing sideface electrodes, or both, whereby the chosen electrodes are, connected to the same polarity AC signal, such that they are in phase, whilst at least one of the end electrodes is electrically grounded.

In one embodiment, the alternating current signal can be a sinusoidal AC signal. Square-wave and/or saw-tooth AC signals can be utilised alone or in sequence with sinusoidal signals.

The rotor element or slider element can be mounted at one end of the piezoelectric element. The rotor element can be greater than, equal to or less than 1 mm in diameter, for example about 0.4 mm.

Three-DOF rotation of the rotor element may be obtainable using the piezoelectric element/electrode combination and the electrical input scheme described herein. This can be achieved by producing rotation about each of the three fundamental axes of three-space by:

inducing rotation about the x-axis by coupling the lateral y-direction vibrational mode with the longitudinal z-direction vibrational mode with a 90 degree phase difference;

inducing rotation about the y-axis by coupling the lateral x-direction vibrational mode with the longitudinal z-direction vibrational mode with a 90 degree phase difference; and

inducing rotation about the z-axis by coupling the lateral x-direction vibrational mode with the lateral y-direction vibrational mode with a 90 degree phase difference.

In yet a further embodiment of the first aspect, the piezoelectric actuator comprises a transducer element. The transducer element can be mounted at one end of the piezoelectric element. The transducer element can be mounted between the piezoelectric element and the rotor element or the piezoelectric element and the slider element.

The transducer element can be used to amplify the output performance of the actuator. In one embodiment, the transducer element comprises a body having a longitudinal axis. The longitudinal axis of the transducer element may be aligned with the longitudinal axis .of the piezoelectric element. The transducer element can have a range of cross-sectional forms defined by one or more inner and/or outer walls and may comprise a solid rod or hollow tubing or a combination of both. Suitable transducer elements are available at sub-millimetre diameters from manufacturers such as Cadence Science (USA).

In one embodiment, slots or cut-outs can be provided in the transducer element.

As used herein, the term “slots” is to be understood as covering any form of cut-out formed in or created on the surface of the transducer element. It is to be understood as covering all forms of cuts, indentations, grooves, pits, holes and the like. This definition also applies to other slots defined herein, including slots formed on the isolation structure.

The slots can be provided in the wall or walls of the transducer element, for example the inner and/or outer walls of the transducer element. Any number, arrangement, size, shape and/or depth of slots may be provided. For example, the slots can have parallel sidewalls, non-parallel sidewalls, be substantially U-shaped or substantially V-shaped. In a preferred embodiment, slots can be arranged in pairs, Whereby the individual slots of a given pair are located on opposing sides of the transducer element with each slot in the pair having the same size, shape and/or depth as its corresponding slot. Where slots are arranged in pairs, each slot of a respective pair of slots can be located at or about 180 degrees of rotation angle from the other, about a longitudinal axis of the transducer element. Any number of such pairs may be provided, however, symmetric provision of the slots is desired. It has been determined that this symmetric arrangement ensures that undesired lateral motion does not result when longitudinal vibration is induced within the actuator.

In yet a further embodiment, the slots can be provided such that the transducer element is symmetrical about two mutually perpendicular planes, wherein the line of intersection of said planes coincides with the longitudinal axis of the transducer element. Where the longitudinal axis of the transducer element provides a z-axis, the slots can be provided such that the transducer element is symmetrical about the x-z plane and the y-z plane. The slots may be inserted such that the transducer element symmetry about each of these planes is the same.

As defined above, the transducer element can be solid or hollow. Where it is a hollow element, the slots may penetrate partially or fully through the wall(s) of the element. The slots can provide greater design flexibility for such actuators, by allowing the lateral vibration modes to be coupled at a common frequency with other modes independently. In addition, including slots in the transducer element allows the vibration modes to be coupled at much shorter transducer element lengths, therefore lowering the actuator length and volume.

The slots can be formed by laser machining. In another embodiment, the slots can be formed by adding material to or creating raised portions on the transducer element in a manner that results in a slot being formed on the transducer element. The number, arrangement, size, shape and/or depth of the slots are parameters that may be strategically set in order to tune the resonant frequencies and optimise the output performance of the actuator.

In yet a further embodiment, rather than using slots, flexural motion of the transducer element can be modified by adding material at appropriate locations to the transducer element. In one embodiment, raised portion regions can be formed on the wall(s) of the transducer element. The raised portion regions can have any desired shape, and for example be nodular or comprise a series of bumps.

As with the provision of slots, the raised portion regions can be arranged in pairs, whereby individual raised portion regions of a given pair are located on opposing sides of the transducer element with each region in the pair having the same size, shape and/or height as its corresponding region. Where raised portion regions are arranged in pairs, each region of a respective pair of regions can be located at or about 180 degrees of rotation angle from the other, about a longitudinal axis of the transducer element. Any number of such pairs may be provided, however, symmetric provision of the regions is desired. It has been determined that this symmetric arrangement ensures that undesired lateral motion does not result when longitudinal vibration is induced within the actuator.

In yet a further embodiment, the raised portion regions can be provided such that the transducer element is symmetrical about two mutually perpendicular planes, wherein the line of intersection of said planes coincides with the longitudinal axis of the transducer element. Where the longitudinal axis of the transducer element provides a z-axis, the regions can be provided such that the transducer element is symmetrical about the x-z plane and the y-z plane. The regions may be provided such that the transducer element symmetry about each of these planes is the same.

In yet another embodiment, the transducer element can be provided with both slots and raised portion regions.

The frequency of the AC signal applied to the piezoelectric element electrodes may be adjusted to correspond with the respective lateral and longitudinal resonant frequencies of the actuator, in order to optimise the output performance. Coupling of these vibration modes, such that they occur at a common resonant frequency, may be achieved by altering the geometric parameters of the actuator.

Any suitable material may be used for the transducer element, including metals, polymers and ceramics. The transducer element can be constructed from a low acoustic-dissipative material, such as stainless steel, in order to minimise the viscous Material energy losses that lower actuation efficiency. Metal rods and tubing are readily available at sub-millimetre diameters from manufacturers such as Cadence Science (USA).

In yet a further embodiment, the actuator can comprise an isolation structure. The isolation structure can be positioned between the piezoelectric element and a mounting.

In one embodiment, the isolation structure can comprise a body consisting of a plurality of segments. In one embodiment, the isolation structure can comprise a two-segment structure. In another embodiment, the isolation structure can comprise greater than two segments in a periodic structure. The segments can differ. In one embodiment, the segments can differ in rigidity relative to each other, ie one segment can have a relatively low rigidity relative to a high rigidity of the other structure. The relative difference in rigidity can be provided by differences in material properties between the two segments and/or by their geometric structures.

For an isolation structure employing a difference in geometric structure between segments, geometrically altered relatively low-rigidity segment(s) may be created in a manner similar to that described herein with reference to the transducer element. For example, slots or raised portion regions may be formed in the wall(s) of a solid or hollow section of the isolation structure.

In one embodiment of a hollow isolation structure, the slots may penetrate partially or fully through the wall(s). The cross-sectional forms of the relatively low and relatively high rigidity segments of the isolation structure can be any suitable shape. For use with the actuator defined herein, the segments of the isolation structure could be cylindrical and have a cylindrical axis aligned with the longitudinal axis of the piezoelectric element. The slots in the isolation structure may again be formed by commercial laser machining or by adding material to or creating raised portions on the transducer element in a manner that results in a slot being formed on the transducer element.

Any number, arrangement, size, shape and/or depth of slots may be formed in the geometrically altered low-rigidity segment(s) of the isolation structure. As above, the slots can have parallel sidewalls, non-parallel sidewalls, be substantially U-shaped or substantially V-shaped. In one embodiment, the slots can be arranged in pairs, whereby the slots of a given pair are located on opposing sides of the segment and have the same size, shape and/or depth. Any number of such pairs may be arranged on the isolation structure. Each slot of a respective pair of slots can be located at or about 180 degrees of rotation angle from the other, about a longitudinal axis of the isolation structure. The symmetric slot configuration ensures that undesired lateral motion does not result when-longitudinal vibration is induced within the actuator.

The slots can be formed such that the geometrically altered relatively low-rigidity segment(s) is symmetrical about two mutually perpendicular planes, wherein the line of intersection of said planes coincides with the longitudinal axis of the isolation structure. Where the longitudinal axis is considered to provide a z-axis, the slots can be provided such that the isolation structure is symmetrical about the y-z plane and the x-z plane. The slots may be inserted such that the symmetry about each of these planes is the same.

The geometrically altered relatively low-rigidity segment(s) of the isolation structure can be formed by removing more material from its wall(s) than the relatively high rigidity segments) via inclusion of the slots. This minimises the structural rigidity of the segment(s), thereby increasing the acoustic impedance mismatch and the isolation efficiency. The isolation structure may then be constructed by assembling a relatively high-relatively low rigidity structure, including a periodic structure, such as by using standard relatively high-rigidity segment(s) with this geometrically altered low-rigidity segment.

Where the isolation structure has raised portion regions, the raised portion regions can have the features of the raised portion regions as described herein as a feature of the transducer element. Again, it will be appreciated that the isolation structure could be provided with both slots and raised portion regions.

Any suitable material may be used to construct the isolation structure, whether using the geometrically altered relatively low-rigidity segment(s) or not. The use of the geometrically altered relatively low-rigidity segment(s) allows for the use of materials with low acoustic absorption factors, which typically have high rigidities prior to geometric alteration via the inclusion of slots. For micro-applications, materials such as stainless steel rods or tubing may be used, which are available from suppliers such as Cadence Science (USA).

The isolation structure, whether constructed using the geometrically altered relatively low-rigidity segment(s) or not, may be tailored to a specific application using its geometrical parameters and material properties. Due to the mismatch in rigidity of the structure, ‘gaps’ become present in the resonant frequency spectrum of the isolation structure. At frequencies within these gaps, the isolation structure will not vibrate if excited. In addition to the material properties, by tuning the geometric parameters of the isolator, such as the diameter, period, volume fraction (portion of the period taken up by each segment) and so forth, it is possible to alter the centre frequency and the bandwidth of these gaps. Any number of periods may be included within the isolation structure, whereby the more periods used, the lower the energy that will be transmitted from the actuator to its mount, but the larger in length it will be. This is again a parameter that can be set depending upon the particular circumstance. p The isolation structure, when constructed using the geometrically altered relatively low-rigidity segment, can be constructed from a single length of stock material. This removes the need for assembly techniques, which may introduce error and inefficiencies to the isolation structure. This may be achieved by selecting a common material, such as stainless steel tubing, and having slots inserted into segments along the length, forming the relatively high-relatively low rigidity structure.

In one embodiment, the overall broadest diameter of the piezoelectric actuator is less than 1 mm, more preferably less than 500 μm, more preferably about 350 μm.

The piezoelectric actuator can be mounted to a micro-guidewire or micro-catheter.

In a second aspect, there is provided a transducer element for use in a piezoelectric actuator, the transducer element comprising a body having one or more walls, wherein slots are provided in and/or raised portion regions are provided on the wall(s) of the transducer element and arranged in pairs, whereby the slots or raised portion regions of a given pair are located on opposing sides of the transducer element.

In one embodiment, the slots can have the same size, shape and/or depth. In the case of the raised portion regions, these can have the same size, shape and/or height.

In this aspect, the slots or raised portion regions can be symmetrically arranged on the body. In this aspect, each slot or raised portion region of a respective pair can be located at or about 180 degrees of rotation angle from the other, about a longitudinal axis of the transducer element.

In a third aspect, there is provided a transducer element for use in a piezoelectric actuator, the transducer element comprising a body having one or more walls, wherein slots are provided in and/or raised portion regions are provided on the wall(s) of the transducer element and arranged such that the transducer element is symmetrical about two mutually perpendicular planes, wherein the line of intersection of said planes coincides with the longitudinal axis of the transducer element.

In the second and third aspects, the transducer element can have in addition to the features of the slots and/or raised portion regions as defined in these aspects, one, some or all of the features of the transducer element defined herein as part of the first aspect of the invention.

The transducer element of the second and third aspects can be mounted to a piezoelectric element, such as the piezoelectric element as defined herein as a component of the first aspect of the invention.

In a fourth aspect, there is provided an isolation structure for use in a piezoelectric actuator, the isolation structure comprising a body consisting of a plurality of segments, said segments including one or more relatively low rigidity segments and one or more relatively high rigidity segments, with the difference in rigidity being provided by differences in material properties between the relatively low rigidity and relatively high rigidity segments and/or by their geometric structures.

In one embodiment of the fourth aspect, the isolation structure can comprise a two-segment or greater segment structure, with the difference in relative rigidity being provided by differences in material properties between the two segments and/or by their geometric structures. In another embodiment, the isolation structure can comprise a plurality of segments in a periodic arrangement.

Where the difference in rigidity is provided by differences in the geometric structures, one or more symmetrically arranged pairs of slots can be provided in said relatively low rigidity segment(s).

Where the difference in rigidity is provided by differences in the geometric structures, one or more symmetrically arranged pairs of raised portion regions can be provided in said relatively high rigidity segment(s).

The slots or raised portion regions of a given pair can be located on opposing sides of the segments in which they are present. The slots can have the same size, shape and/or depth. The raised portion regions can have the same size, shape and/or height. Each slot or raised portion region of a respective pair can be located at or about 180 degrees of rotation angle from the other, about a longitudinal axis of the isolation structure. The slots or raised portion regions can be arranged such that said segment(s) are symmetrical about two mutually perpendicular planes, wherein the line of intersection of said planes coincides with the longitudinal axis of the isolation structure.

The isolation structure of the fourth aspect can be mounted to a piezoelectric element, such as the piezoelectric element as defined herein as a component of the first aspect of the invention.

In yet another embodiment, the isolation structure can be formed with a piezoelectric element out of a single length of stock material so forming a piezoelectric actuator, such as a multi-DOF actuator. In one embodiment, the length of stock material may be a solid or hollow titanium tube, which then has PZT material selectively grown on the outer surface. This may be followed by insertion of slots into the equivalent transducer element and low-rigidity segments of the actuator-isolation structure assembly. Alternatively, the slots could be inserted prior to growing the PZT material, whereby the material may be selectively grown on or over the top of the slots.

The isolation structure of the fourth aspect can further have one, some or all of the features of the isolation structure as defined herein as part of the first aspect of the invention.

### BRIEF DESCRIPTION OF THE DRAWINGS

By way of example only, the present invention is now described with reference to the accompanying drawings, in which:

FIGS. 1a and 1b depict embodiments of piezoelectric elements according to the present invention;

FIGS. 2a and 2b depict electrical schemes that can be used to excite the lateral (x-direction) and longitudinal (z-direction) vibration modes, respectively, within a piezoelectric actuator according to the present invention;

FIGS. 3a, 3b and 3c depict the electrical schemes used to couple the fundamental vibration modes, such as are depicted in FIGS. 2a and 2b, in order to generate rotation of a rotor about the three fundamental axes of three-space, here the x-, y- and z-axes, respectively;

FIGS. 4a to 4c depict embodiments of transducer elements according to the present invention;

FIG. 5 depicts one embodiment of an isolation structure according to the present invention for mounting to a piezoelectric element;

FIG. 6 depicts one embodiment of a piezoelectric actuator according to the present invention;

FIGS. 7a, 7b and 7c depict how a micro-motor can produce rotation about the longitudinal z-axis, the transverse x-axis and the transverse y-axis, respectively, via the coupling of orthogonal flexural and axial vibrational modes;

FIG. 8(a) depicts. an embodiment of a micro-motor comprising a hollow cylindrical transducer (outer diameter 230 μm and inner diameter 110 μm) mounted atop a 250×250×500 μm PZT piezoelectric element, with 30×100 μm slots, typically spaced 181 μm apart and penetrating right the way through the wall, inserted within the transducer walls symmetrically about the x-z and y-z planes in order to lower the flexural resonant frequencies. The first flexural (FIG. 8(b)), second flexural (FIG. 8(c)) and first axial (FIG. 8(d)) vibrational mode shapes show the relative FEA-predicted displacements;

FIG. 9 depicts measured resonant frequencies vs transducer length. The transducer length was varied in order to couple the second flexural resonant frequencies with an axial resonant frequency for the two transverse axes (x and y) of rotation, which was achieved at a length of 1450 μm. The first flexural modes were used for the longitudinal axis of rotation;

FIG. 10 depicts a prototype micro-motor constructed using electrically conductive epoxy to bond the transducer to the PZT element, to bond the PZT element to an insulated substrate, and to connect gold power wires to the PZT element;

FIG. 11 depicts measured torque of the micro-motor, shown as a function of rotational speed, about each axis calculated based on the angular acceleration of the rotor during its transient startup phase. The operating frequency of the transverse x, transverse y and longitudinal z axes was 456, 462 and 191 kHz, respectively;

FIG. 12 depicts how a continual burst-triggered control scheme was employed to lower the rotational speeds to between 6 and 20 RPM. The provided still images were taken from videos captured of the micro-motor operation about three orthogonal axes of rotation: (a) longitudinal z-axis, (b) transverse x-axis and (c) transverse y-axis. For visualization purposes, a 1 mm length of nylon was bonded to the rotor;

FIG. 13 is a graph depicting normalised bandwidth and centre frequency of an isolation structure formed from a stainless steel-nylon composite. Lines are fitted for visualization purposes;

FIG. 14 depicts a prototype of an isolation structure according to the present invention that was constructed;

FIG. 15 is a graph depicting the numerical and experimental resonant frequency spectra of the tested isolation structure showing a stopband between modes 5 and 6, with a centre frequency of 520 kHz and bandwidth of 380 kHz. Lines are fitted for visualization purposes; and

FIG. 16 depicts the isolation structure that was excited at the centre frequency of the first stopband (520 kHz), (a) experimentally and (b) numerically. In (a) the vibration displacement is perpendicular to the plane of the page, whilst in (b) it is displayed in-plane to show the displacement profile. The vibration amplitude at the connecting interfaces is shown in the table of the figure (inset).

### PREFERRED MODE

The generation of motion from a piezoelectric actuator or motor is achieved by using a piezoelectric element to periodically excite the resonant vibrational tendencies of a transducer. Based on the shape of these vibrational modes and the actuator's geometry, various output motions including translation and rotation may be produced.

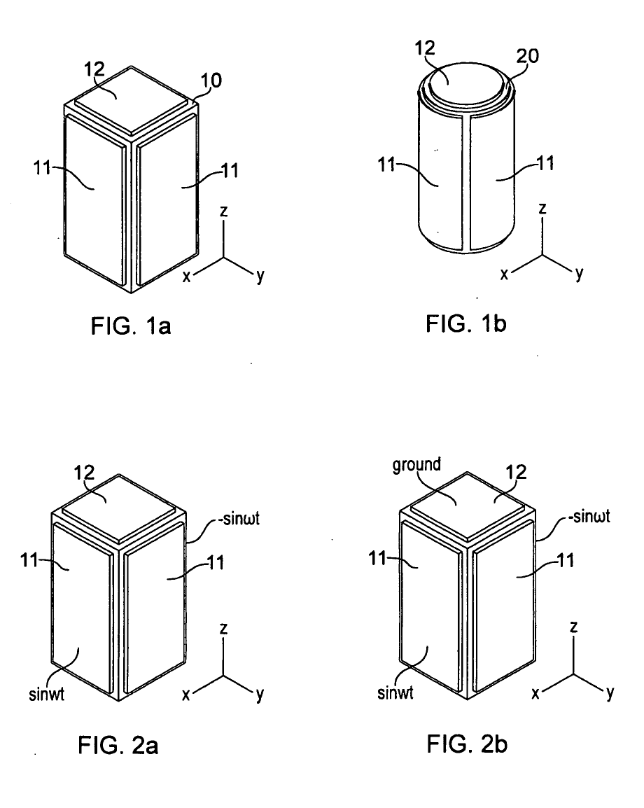

In FIGS. 1a and 1b, embodiments of a piezoelectric element 10,20 of a piezoelectric actuator are depicted. While the elements can take many different shapes, FIG. 1a depicts a rectangular block element and FIG. 1b depicts a cylindrical element.

The piezoelectric element can be constructed from a variety of materials, including lead zirconate titanate (PZT), which can be commercially obtained from suppliers such as Fuji Ceramics Corporation (Japan).

The piezoelectric element 10 is provided with four sidefaces, each having a separate sideface electrode 11 while depicted piezoelectric element 20 has one sideface having four sideface electrodes 11. Both embodiments have endface electrodes 12. These electrodes are used for exciting the vibrational modes within the actuator. In the embodiments, it can be assumed that endface electrodes are disposed on the depicted respective lower ends of the elements 10,20.

As depicted in FIGS. 1a and 1b, the two pairs of opposing sideface electrodes of the piezoelectric element 10,20 are located such that the two axes perpendicular to the planes in which the sideface electrodes 11 reside are:

perpendicular to each other, and

perpendicular to the axis that is Perpendicular to the plane in which the endface electrode(s) 12 resides (the longitudinal axis of the element).

For example, the sideface electrodes 11 of the piezoelectric element 10 in FIG. 1a are located such that:

two are parallel to the y-z plane, and

two are parallel to the x-z plane.

It is to be understood that it is an option to include fewer electrodes than the four sideface electrodes 11 and the two endface electrodes 12, in the case that motion is not required about or in all of the three fundamental axes.

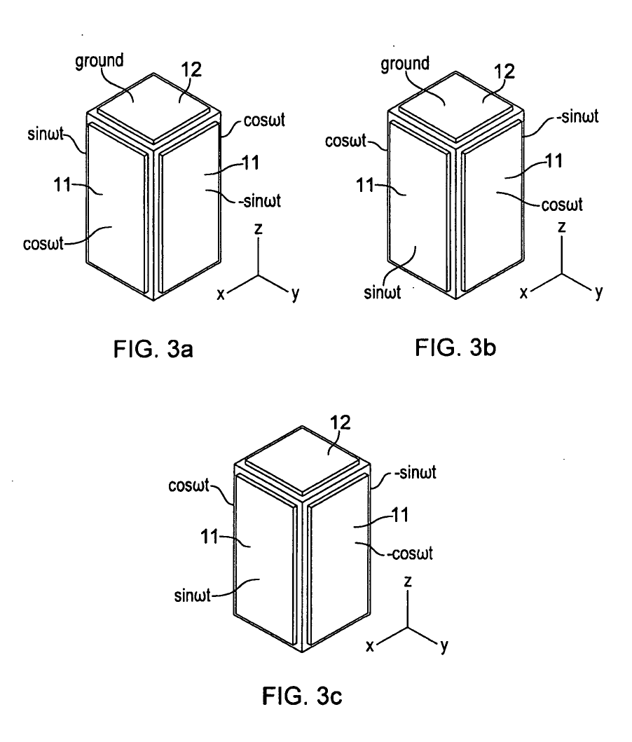

It will be appreciated in reviewing FIGS. 2a, 2b, 3a and 3b that some of the electrodes to which electrical inputs are applied are not visible. Furthermore, in these Figs, the reference to sinusoidal AC signals are also only provided as an example, with other AC signals such as square-wave and/or saw-tooth possible.

Lateral vibration of the piezoelectric element, such as in the x-direction in FIG. 2a, may be induced by applying a sinusoidal AC signal to a pair of opposing sideface electrodes 11, whereby one electrode could be connected to a positive polarity AC signal, while the other is connected to a negative polarity AC signal, such that the two signals are 180 degrees out of phase (see FIG. 2a). This maximises the lateral vibration amplitude that is obtainable for a given input voltage.

Longitudinal vibration of the piezoelectric element, such as in the z-direction in FIG. 2b, may be induced by applying a sinusoidal AC signal to one, or both, pair(s) of opposing sideface electrodes 11, whereby the chosen electrodes are connected to the same polarity AC signal such that they are in phase, whilst one of the endface electrodes 12 is electrically grounded (see FIG. 2b).

Three-DOF rotation of a rotor (eg a 0.397 mm ball rotor) placed directly or indirectly atop the depicted piezoelectric element may be obtainable via this electrical input scheme. Rotation about each of the three fundamental axes of three-space may be induced as follows:

i. rotation about the x-axis may be induced by coupling the lateral y-direction vibration mode with the longitudinal z-direction vibration mode with a 90 degree phase difference (see FIG. 3a);

ii. rotation about the y-axis may be induced by coupling the lateral x-direction vibration mode with the longitudinal z-direction vibration mode with a 90 degree phase difference (see FIG. 3b); and

iii. rotation about the z-axis may be induced by coupling the lateral x-direction vibration mode with the lateral y-direction vibration mode with a 90 degree phase difference (see FIG. 3c).

A piezoelectric actuator according to the present invention, including a piezoelectric actuator having a piezoelectric element as described with reference to FIGS. 1 to 3c, can further comprise a transducer element that is mounted atop the piezoelectric element, in order to amplify the output performance of the actuator.

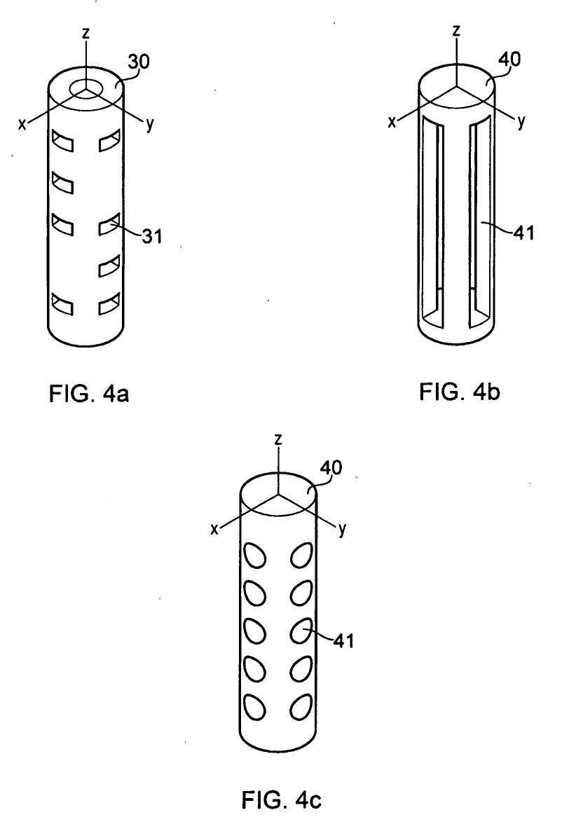

The longitudinal axis of the transducer element may align with the longitudinal axis of the piezoelectric element 10,20 and may take on many cross-sectional forms. As depicted in FIGS. 4a-4c, the transducer element may be formed from a hollow tube 30 or a solid rod 40. The depicted transducer elements can be sub-millimetre in diameter and formed from materials supplied from suitable manufacturers such as Cadence Science (USA).

As depicted in FIGS. 4a-4c, slots 31,41 can be provided in the wall(s) of the transducer element. In the depicted embodiments, the slots are arranged in pairs and it will be appreciated that the slot pairs can come in any number, arrangement, size, shape and/or depth, including as depicted. The slot arrangement of a given pair is such that slots are located on opposing sides of the transducer element 30,40 and have the same size, shape and depth. While certain arrangements are depicted, any number of such pairs may be inserted. This symmetric insertion configuration ensures that undesired lateral motion does not result when longitudinal vibration is induced within the actuator.

The slots 31 of transducer element 30 as depicted in FIG. 4a are inserted such that the transducer element is symmetrical about two planes, for some angular orientation about the longitudinal axis, such as the x-z and y-z planes in FIG. 4a. These planes will be perpendicular to each other, and their line of intersection will be coincident with the longitudinal axis of the transducer element.

The slots 41 depicted in FIGS. 4b and 4c can be inserted such that the transducer element symmetry about each of these planes is the same.

The depicted slots may be inserted into the transducer element, and may penetrate partially or fully through the wall in the case of the hollow element depicted in FIG. 3a.

The slots provide greater design flexibility for such actuators, by allowing the lateral vibration modes to be coupled at a common frequency with other modes independently. In addition, including slots in the transducer allows the vibration modes to be coupled at much shorter transducer lengths, therefore lowering the actuator length and volume. As described, such slots could be inserted via commercial laser machining, however, other formation techniques could be employed including adding material to the transducer to form the slots. The number, arrangement, size, shape and/or depth of slots are parameters that may be strategically set in order to tune the resonant frequencies and optimise the output performance of the actuator.

While an embodiment with slots is depicted, it will be appreciated from the description as provided herein that the transducer element can be provided instead or in addition with raised portion regions having the features as defined.

The frequency of the AC signal (ω) applied to the piezoelectric element electrodes may be adjusted to correspond with the respective lateral and longitudinal resonant frequencies of the actuator, in order to optimise the output performance. Coupling of these vibration modes, such that they occur at a common resonant frequency, may be achieved by altering the geometric parameters of the actuator.

Any suitable material may be used for the transducer elements depicted in FIGS. 4a-4c, including metals, polymers and ceramics. Preferably, the transducer element can be constructed from a low acoustic-dissipative material, such as stainless steel, in order to minimise the viscous material energy losses that lower actuation efficiency. Metal rod and tubing are readily available at sub-millimetre diameters from manufacturers such as Cadence Science (USA).

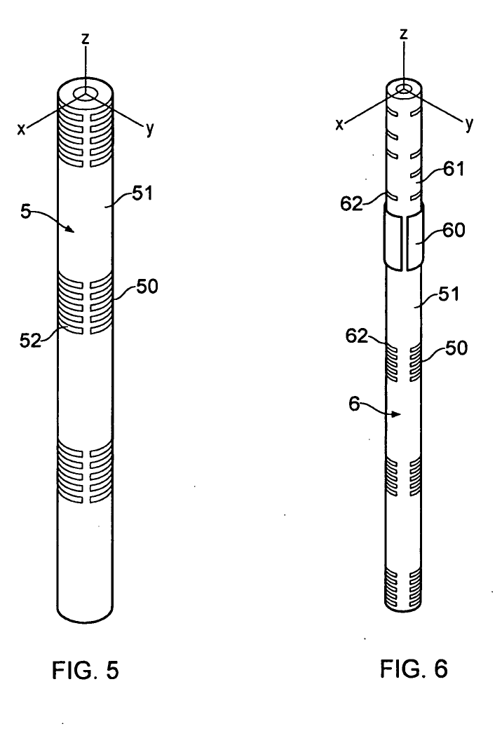

FIG. 5 depicts one embodiment of an isolation structure 5 according to the present invention. The isolation structure 5 is constructed by forming a two-segment 50,51 periodic structure, whereby the two segments differ in rigidity mostly via their material properties, or via their geometric structures, or via both.

For an isolation structure employing a difference in geometric structure, geometrically altered relatively low-rigidity segment(s) 50 may be created in much the same manner as the transducer element 30,40 defined herein, whereby slots 52 are inserted into the wall(s) of a solid or hollow section. The slots 52 may penetrate partially or fully through the wall(s), in the hollow case. The cross-sectional forms of the relatively low 50 and relatively high 51 rigidity segments of the isolation structure 5 can come in a variety of suitable forms. For use with the piezoelectric element 20 described herein, the segments of the isolation structure 5 can be cylindrical, with the longitudinal axis of the cylinder being aligned with the longitudinal axis of the piezoelectric element 20. The slots 52 may again be inserted via commercial laser machining or other techniques as described herein.

As with the transducer element 30,40, the slots used in the isolation structure 5 can come in any number, arrangement, size, shape and/or depth. In the depicted embodiment, the slots 52 are arranged in pairs, whereby the slots 52 of a given pair are located on opposing sides of the segment 50 and have the same size, shape and depth. Any number of such pairs may be inserted. This symmetric insertion configuration ensures that undesired lateral motion does not result when longitudinal vibration is induced within the actuator.

As depicted, the slots 52 can be positioned such that the geometrically altered relatively low-rigidity segment(s) is symmetrical about two planes, for some angular orientation about the longitudinal axis of the segment(s), such as the x-z and y-z planes in FIG. 5. These planes will be perpendicular to each other, and their line of intersection will be coincident with the longitudinal axis of the segment(s). The slots 52 may be inserted such that the symmetry about each of these planes is the same, as shown in FIG. 5.

The geometrically altered relatively low-rigidity segment(s) 50 will comprise less material via inclusion of the slots 52 in comparison to the relatively high-rigidity segment(s) 51. This minimises the structural rigidity of the segment(s) 50, thereby increasing the acoustic impedance mismatch and the isolation efficiency. The isolation structure 5 may be constructed by forming a relatively high 51—relatively low 50 rigidity structure.

As described herein, and while not depicted, the relatively high rigidity segment 51 can have one or more symmetrically arranged pairs of raised portion regions.

Any suitable material may be used to construct the isolation structure 5, whether using the geometrically altered relatively low-rigidity segment(s) 50 or not. The use of the geometrically altered low-rigidity segment(s) 50 allows for the use of materials with low acoustic absorption factors, which typically have high rigidities prior to geometric alteration via the inclusion of slots. For micro applications, materials such as stainless steel rod or tubing may be used, which are commercially available at low-cost from suppliers such as Cadence Science (USA).

The isolation structure 5, whether constructed as depicted using the geometrically altered relatively low-rigidity segment(s), 50 or not, may be tailored to a specific application using its geometrical parameters and material properties. Due to the mismatch in rigidity of the structure, ‘gaps’ become present in the resonant frequency spectrum of the isolation structure 5. At frequencies within these gaps, the isolation structure 5 will not vibrate if excited. In addition to the material properties, by tuning the geometric parameters of the isolation structure 5, such as the diameter, period, volume fraction (portion of the period taken up by each segment) and so forth, it is possible to alter the centre frequency and the bandwidth of these gaps. Any number of periods may be included within the isolation structure 5, whereby the more periods used, the lower the energy that will be transmitted from the actuator to its mount, but the larger in length it will be. This is again a parameter that can be set depending upon the particular circumstance.

In one embodiment, the isolation structure using the depicted geometrically altered relatively low-rigidity segment(s) 50 can be constructed from a single length of stock material (as is depicted in FIG. 5). This removes the need for assembly techniques, which may introduce error and inefficiencies to the isolation structure 5. This may be achieved by selecting a common material, such as stainless steel tubing, and inserting slots 52 and/or raised portion regions (not depicted) into spaced-apart segments along the length, forming the relatively high 51—relatively low 50 rigidity structure.

A further embodiment of a multi-DOF piezoelectric actuator structure 6 is depicted in FIG. 6. In this embodiment, the structure is constructed out of a single length of stock material. For example, the actuator may be constructed from a base of solid or hollow titanium tube 61, which then has PZT material selectively grown on the outer surface 60 to form a piezoelectric element section. This may be followed by insertion of slots 62 to form a transducer element section and to form relatively low-rigidity segments 50 of an isolation structure section. Alternatively, the slots 62 could be inserted prior to growing the PZT material 60, whereby the material may be selectively grown as shown in FIG. 6, or over the top of the slots.

Description of Development of Prototype Actuator

A prototype micro-motor or actuator 7 using the features defined herein was developed and comprised a hollow cylindrical transducer 70 that is mounted atop and excited by a single lead zirconate titanate (PZT) piezoelectric element 71, to drive a ball rotor 72.

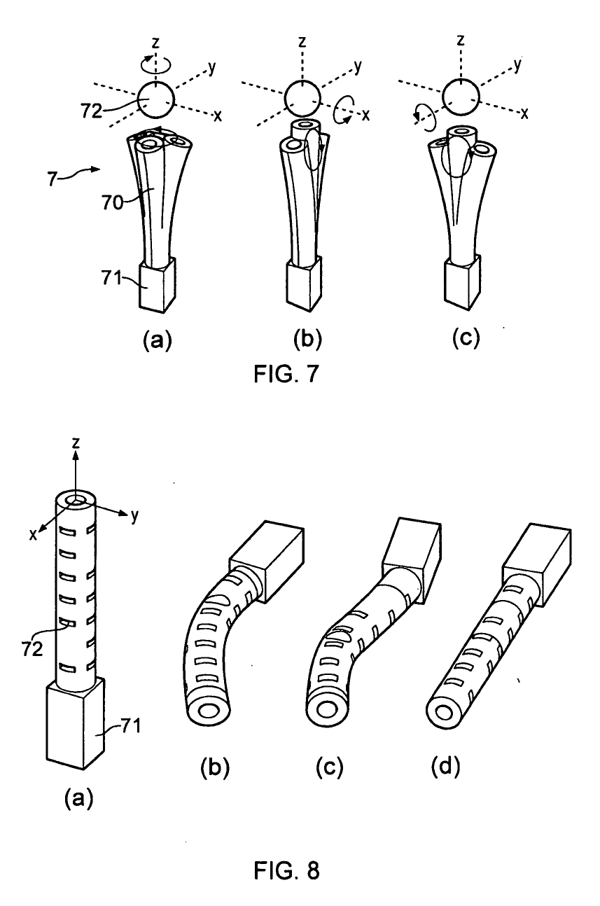

In this prototype, rotation can be generated about the longitudinal axis via the coupling of two flexural vibrational modes (see FIG. 7(a)). In addition, rotation about each of the transverse axes can be generated via the coupling of a flexural vibrational mode with an axial mode within the transducer (see FIGS. 7(b) and 7(c)). In order to realize these output rotations, each vibrational mode must be excited with a quarter wavelength phase difference relative to the other.. By altering which of the two vibrational modes leads in phase, the rotation about any axis may be reversed. The net result is three-DOF reversible rotation, whereby rotation is present about two orthogonal transverse axes (x and y) and about the longitudinal axis (z).

In order to excite the necessary vibrational modes within the transducer, a method of generating flexural and axial motion within the PZT piezoelectric element was devised.

The PZT element used in this design is polarized in the longitudinal direction. By imposing an electric differential across two opposing sides of the element, it is possible to force the element to bend via the d₃₁ piezoelectric strain coupling. Alternatively, by applying an equal electric potential across two opposing sides of the element, with either the upper or lower longitudinal electrode grounded; the element can be forced to extend axially.

The performance of such resonant motors hinges on the level of accuracy to which the two orthogonal vibrational modes are coupled. This coupling is achieved by tuning the geometrical parameters of the transducer in order to match the two resonant frequencies to within the desired degree of accuracy. To conduct the frequency matching in this example, a finite element analysis (FEA) was undertaken.

The FEA package chosen to conduct the design and development of the three-DOF micro-motor was ANSYS 11.0 (ANSYS Inc., Canonsburg, Pa.), based on its unique suitability for micro-electro-mechanical systems (MEMS) and piezoelectric materials applications. A modal analysis was initially conducted to predict and tune the resonant frequencies of the micro-motor's vibrational modes.

Upon conducting the FEA, the micro-motor was modelled as a full unit minus the rotor. Included in the model were two epoxy bonds to join the PZT element to the transducer, and to fix the micro-motor to a substrate for testing. An electrically conductive high strength epoxy was selected (Epotek H20E, Epoxy Technology Inc., Bellerica, Mass.), and the bond thickness was taken to be 10 μm, which was later verified through a numerical-experimental validation procedure. Based on the availability of standard hypodermic needle tubing, the inner and outer diameters of, the cylindrical transducer were set at 110 μm and 230 μm, respectively. The dimensions for the PZT elements were then set at 250×250×500 μm, based on the desired scale of the motor, manufacturability and resonant displacement maximization under these constraints. The material for the transducer was chosen to be stainless steel 304, and the material properties for the piezoelectric element were typical of PZT. Knowledge of these parameters a priori left the transducer length as the only variable for tuning the resonant frequencies of the motor.

Upon varying the length of the transducer, it became increasingly difficult to induce flexure in the micro-motor at shorter lengths. In addition, larger transducer lengths were found to be necessary to sufficiently lower the frequency of the axial vibrational mode for coupling with the flexural vibrational modes, in order to obtain transverse axis rotation. Since it is desirable to minimize the transducer length for use in micro-applications, strategic weakening of the transducer walls was ideated in order to promote flexural motion at smaller transducer lengths, at the expense of simplicity. This strategic weakening was achieved by inserting slots 72 located symmetrically in the transducer walls, as shown in FIG. 8(a). Theft slots were found to be the most suitable of many designs explored on the basis that they substantially lowered all resonant frequencies whilst maintaining modal displacement purity. Maximizing the purity of the independent vibrational modes (FIGS. 8(b)-(d)) is important in order to obtain pure, controlled rotation of the rotor about each orthogonal axis.

To further aid with this modal purity, two slots were made Unique to each transverse axis in order to create a small, precise frequency difference between the flexural vibrational mode in each axis.

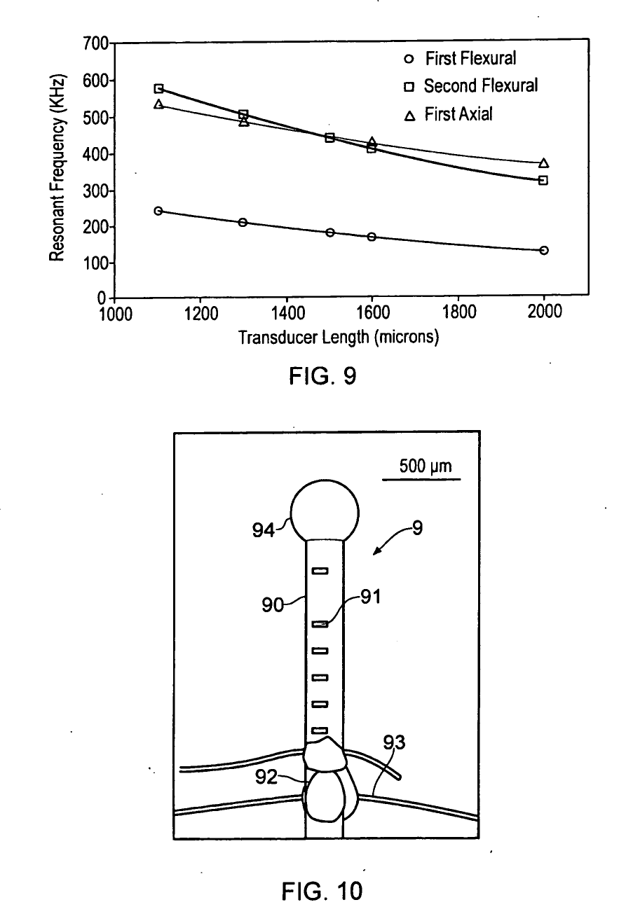

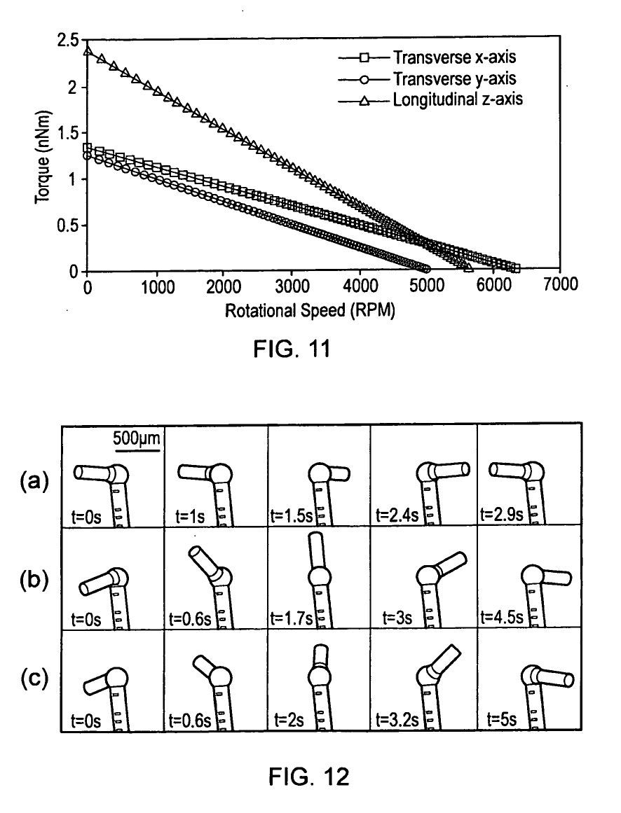

FIG. 9 shows the effect that varying the transducer length-with the design of FIG. 7 had on both the flexural and axial vibrational modes. Specifically, modal frequency coupling for the micro-motor required the second flexural vibrational modes to be closely matched with the first axial vibrational mode. It is evident that this is the case at a transducer length of 1450 μm for the geometry used.

The prototype 9 was then constructed in accordance with the dimensions of FIG. 8. The transducers 90 were cut to length from a stock of standard hollow hypodermic needle tubing (Cadence Science, New York) and had the slots 91 inserted via laser machining (Laser Micromachining Solutions, Macquarie University, Australia). The piezoelectric elements 92 (Fuji C-203, Fuji Ceramics Inc., Japan) had 50 μm diameter gold wires 93 bonded to them for power transmission using the same electrically conductive high strength epoxy as above.

FIG. 10 shows the completed prototype 9. The rotor used for the performance evaluation of the micro-motor was a chrome 0.397 mm diameter ball 94 (Small Parts and Bearings, Queensland, Australia).

The frequencies of the vibrational modes were first experimentally measured using a laser Doppler vibrometer (Polytec Inc., Tustin, Calif.) for comparison with those predicted via the FEA, in order to validate the numerical model. The following (Table 1) shows this comparison, where the error is normalized against the predicted values. Evidently, all experimental frequencies are within 4% percent of those predicted, for which the error may be attributed to the difficulties associated with the fabrication and hand assembly of a motor of this size. Hence, the FEA model, including the epoxy bonds and the electrical and mechanical boundary conditions, used to design the micromotor was considered valid.

TABLE 1
Comparison between the FEA-predicted and experimental
resonant frequencies (f) in kHz. The error (%) is normalized
against the predicted f.

| Mode/axis | Predicted f | Experimental f | Error |
|---|---|---|---|
| First x-flexure | 193.6 | 187.5 | 3.15 |
| First y-flexure | 199.1 | 195.0 | 2.06 |
| Second x-flexure | 471.3 | 461.9 | 1.99 |
| Second y-flexure | 462.1 | 458.7 | 0.74 |
| First z-axial | 461.1 | 464.4 | −0.72 |

Measurement of the performance of the micro-motor involved measurement of the rotational velocity of the rotor during the transient startup period to infer the acceleration and thus torque of the motor. A laser Doppler velocimeter (Canon LV-20Z, USA) was used to measure the tangential velocity of the ball rotor, which could then be converted to a rotational velocity. A WF1996 (NF Corp., Japan) signal generator with dual-phased output and triggering capabilities was used to generate the two-phased voltages applied to the micro-motor. Each input was subsequently amplified using BA4825 (NF Corp., Japan) power amplifiers. The input signals to the micro-motor and the output voltage from the laser. Doppler velocimeter, which is proportional to the rotor speed, were monitored and logged using a digital oscilloscope (LeCroy WaveJet, USA).

The experimental rotational speed of the rotor about all three axes as a function of time was fitted with an exponential function. The equations were subsequently differentiated to give expression's for the angular acceleration of the rotor, allowing the torque of the micromotor to be calculated. FIG. 1 shows the result of these torque calculations for the three orthogonal axes, which have been plotted against the rotational speed of the rotor. The voltage applied for all axes was 21.2 VRMS, and the operating frequency of the transverse x, transverse y and longitudinal z axes was 456, 462 and 191 kHz, respectively. The peak (stall) torque and maximum (no load) rotational speed for the transverse x, transverse y and longitudinal z axes were 1.33 nNm and 6300 RPM, 1.23 nNm and 4950 RPM, and 2.38 nNm and 5630 RPM, respectively. The values presented herein represent the average capability of the micro-motor, with peak torque and rotational speed figures of up to twice these having been observed. The inventor thus believes that as the technological state of top-down manufacturing and assembly improves at the micro-scale, significant performance gains will be possible for this micro-motor.

Piezoelectric micro-motors typically operate with very high rotational speeds (>>20 RPS). Whilst these rotational speeds are desirable for a variety of applications, such as micro-drilling and robotic propulsion, they are, much too high for other applications. For example, in the case of MIS, low-speed control is required in applications such as surgeon physiological tremor suppression, micro-robotic forceps, and endoscopic and laparoscopic surgery. For this purpose, the input drive signal was continuously burst-triggered for all three axes of rotation, where the burst duration (mark) was controlled similar to a modulation duty cycle. FIG. 12 shows still images taken from videos that were captured using this control of the micro-motor about the three orthogonal axes of rotation. The control scheme, resulted in a reduction in the rotational speeds from. approximately 5000 RPM to 10 RPM for the mark used, which is aptly suitable for fine position control by a surgical practitioner.

Based on work conducted on the prototype, a true micro-motor capable of reversible three-DOF rotation with a major diameter of 350 μm has been designed, prototyped and tested. In order to couple the resonant frequencies of the flexural and axial vibrational modes at shorter transducer lengths, slots were inserted within the walls of the transducer. The torque of the micro-motor was found to be on the order of 1-2 nNm at 21.2 VRMS, with rotational speeds- of around 5000-6000 RPM. An electrical control scheme was employed to demonstrate the ability to operate these micro-motors not only at high speeds, but also at the low speeds necessary for many applications, with reduced speeds of between 6 and 20 RPM demonstrated. It is anticipated that this micro-motor could be either integrated with existing micro-robotic MIS tooling, providing the necessary catalyst for further miniaturization of these technologies, or used to further the technological advancement of manually operated diagnosis and treatment micro MIS tooling, both of which will aid surgeons in their quest for better patient care.

Descriptions of Experiments on Protoype Isolation Structure

A sub-millimetre cylindrical design of an isolation structure was numerically developed and experimentally tested. This micro-structure was designed to locate between a resonant micro-actuator and its mount in order to isolate the acoustic behaviour. The formation of acoustic stopbands within the resonant frequency spectrum was exploited. The cylindrical configuration was chosen due to its versatility. The study focussed on the isolation of flexural waves, but can readily incorporate the case of longitudinal waves.

The characterization of the resonant tendencies of a free isotropic cylindrical waveguide may be achieved via Pochhammer's frequency equation. Due to the large extent of coupling within Pochhammer's equation for the case of flexural waves, a closed-form solution remains elusive. As a result, alternative techniques have been developed over the years to allow an approximate solution to be effected. However, such solutions and analyses have only been developed for the case of the simple free cylinder and are unable to accommodate the complications associated with inhomogeneities and complex boundary conditions. To overcome this, a finite element analysis (FEA) was used to predict the resonant frequencies of the isolation structure, thus making it possible to plot the resonant frequency spectrum.

A composite structure was devised comprising nylon-6 . monofilament and stainless steel 304 rod, on the basis that both are readily available at sub-millimetre diameters. A parametric model comprising a periodic structure of these materials was developed using ANSYS 11.0 (ANSYS Inc., Canonsburg, Pa., USA). The diameters of the stainless steel and nylon segments were set at 300 μm, leaving the composite period length, volume fraction, and number of periods as variables for tuning and optimizing the acoustic isolation.

Initially, a series of modal analyses were carried out to predict the resonant frequencies of the model using the FEA package, in order to ascertain the structure's sensitivity to these variables. To produce a lateral dispersion spectrum, the eigenmode number was related to the wavenumber. The angular wavenumber, k, is given by 2π/λ, where λ is the acoustic wavelength. For waveguide isolation structures, a stopband occurs whenever the acoustic wavelength is equal to a scalar fraction of the composite period, d. Hence, the wavenumber for the nth stopband is given by

kₙ=2πn/d; n=1, 2, 3, . . . (1)

Since the eigenmode number, m, is related to the wavelength via 2L/λ, where L is the total length of the structure, the wavenumber of a given eigenmode for a structure with p composite periods is

kₘ=πm/pd; m=1, 2, 3, . . . (2)

Whenever equations (1) and (2) are equal, a stopband will exist.

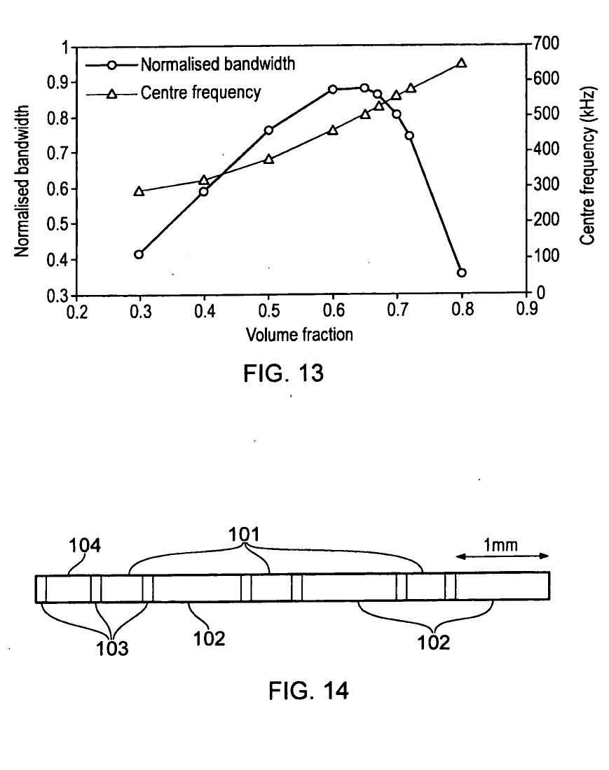

The effect that the composite volume fraction and period length had on the centre frequency and bandwidth of the acoustic stopbands was studied. It was established that the greatest control over the centre frequency of the stopbands could be gained by adjusting the period length rather than the volume fraction. As it is desirable that the centre frequency of e stopband coincides with the operating frequency of the resonant actuator it is to be coupled with, the composite period length should be adjusted last. The volume fraction, on the other hand, was found to have a very strong influence over both the centre frequency and the bandwidth of the stopbands. As the bandwidth of a given stopband is related to the centre frequency, in that higher frequency stopbands tend to have greater bandwidths, the bandwidth was normalized against the centre frequency. From FIG. 13 it is clear that for the stainless-steel-nylon composite, the optimum volume fraction is around 0.65, that is, the period should comprise 65% stainless steel. The centre frequency of the first stopband was then adjusted close to 500 kHz using the composite period length, yielding a period of 1500 μm. This frequency was chosen based on the operating frequency of a typical ultrasonic micro-actuator. Finally, by the visual inspection of the FEA displacements, three periods of the composite were deemed sufficient for experimentation.

A prototype was constructed comprising three composite periods of nylon 101 and stainless steel 102, a volume fraction of 0.65 and a period of 1500 μm (FIG. 14). The stainless steel (Cadence Science, NY, USA) and nylon (Australian Monofil Co., Australia) segments were cut to length via laser machining (Laser Micromachining Solutions, Macquarie University, Australia) and bonded together at bonds 103 using high strength epoxy (Epotek H20E, Epoxy Technology Inc., Bellerica, Mass., USA). The bond thickness, assumed to be 10 μm, was accounted for by reducing the length of the nylon segments by the same amount, as the acoustic impedance of the epoxy is very similar to that of nylon. Flexural waves were excited within the isolation structure using a lead zirconate titanate (PZT) piezoelectric element 104 of dimensions 250×250×500 μm (Fuji C-203, Fuji Ceramics Inc., Japan), which was bonded to the structure and the substrate using the same epoxy.

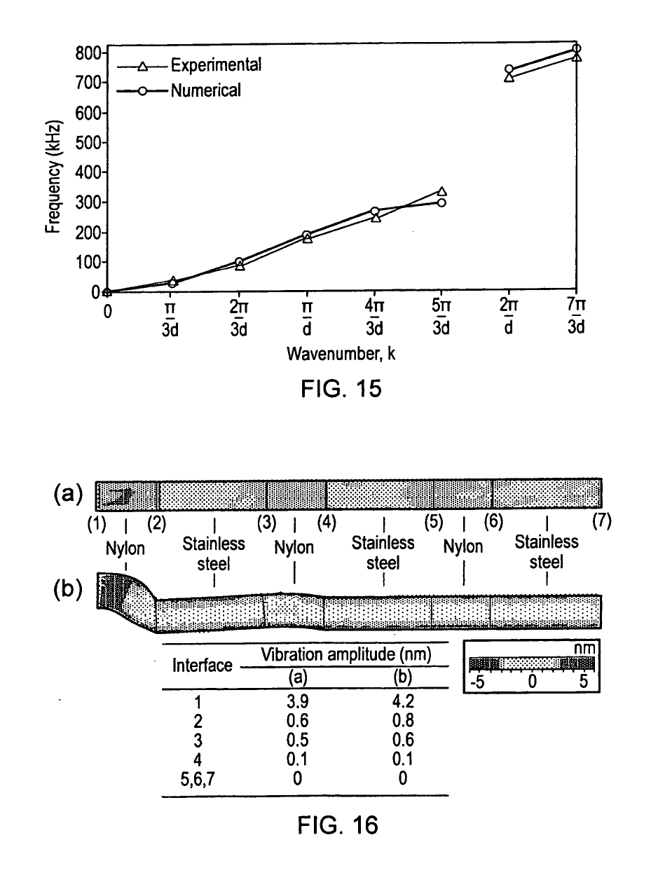

The lateral resonant frequencies of the prototype were measured using a laser Doppler vibrometer (LDV) (Polytec Inc., Tustin, Calif., USA) for comparison with those predicted numerically, as shown in FIG. 15. Here, the eigenmode number was again used to compute the wavenumber using equation (2). Evident in FIG. 15 is the first acoustic stopband, located with an experimental centre frequency and bandwidth of 520 and 380 kHz, respectively. FIG. 15 also demonstrates an excellent quantitative agreement between the numerically predicted and experimentally measured lateral dispersion spectra, validating the numerical model and the use of a FEA for designing the isolation structure.

In order to verify the acoustic isolation performance of the structure within the stopband, the prototype was excited with a flexural wave at the centre frequency, and the LDV was used to scan its vibration displacement (FIG. 16(a)). By observation and comparison with the FEA harmonic excitation of the isolation structure (FIG. 16(b)), the acoustic wave is almost completely isolated within the first period, and is fully isolated before the end of the structure. Hence, depending upon the application specific requirements, one period of this structure should be sufficient.

Based on these results, the isolation structure proved capable of isolating acoustic waves in the long wavelength limit, such as those generated by resonant micro-actuators. The stainless-steel-nylon composite isolation structure produced a sufficient 380 kHz bandwidth acoustic stopband with a centre frequency of 520 kHz.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

1. A piezoelectric actuator capable of generating motion of a rotor element or slider element, about or in, each of the three fundamental axes of three dimensional space, the actuator comprising a piezoelectric element having a body having:
one or more sidefaces,
a first endface, and
a second endface;
wherein said at least one or more sidefaces comprise a plurality of separate sideface electrode(s) and at least one of the first or second endfaces comprises an endface electrode.

2. The piezoelectric actuator of claim 1 wherein the body of the piezoelectric element is a rectangular block.

3. The piezoelectric actuator of claim 1 wherein the body has four sidefaces, each of the sidefaces comprising a separate sideface electrode.

4. The piezoelectric actuator of claim 1 wherein the body has one sideface comprising four sideface electrodes.

5. The piezoelectric actuator of claim 1 wherein the body of the piezoelectric element is a cylinder.

6. The piezoelectric actuator of claim 3 wherein the four sideface electrodes are arranged such that they form two pairs, whereby the two sideface electrodes of a given pair are in opposing locations on the piezoelectric element.

7. The piezoelectric actuator of claim 6 wherein each electrode of a pair of sideface electrodes is located at or about 180 degrees of rotation angle from the other, about a longitudinal axis of the piezoelectric element.

8. The piezoelectric actuator of claim 7 wherein the two pairs of opposing sideface electrodes of the piezoelectric element are located such that the two axes perpendicular to the planes in which the sideface electrodes reside are:
perpendicular to each other, and
perpendicular to the axis that is perpendicular to the plane in which the endface electrode(s) resides.

9. The piezoelectric actuator of claim 8 wherein the longitudinal axis of the body provides a z-axis of the actuator, the sideface electrodes of the piezoelectric element are located such that:
two are parallel to the y-z plane, and
two are parallel to the x-z plane.

10. The piezoelectric actuator of claim 1 wherein the body of the piezoelectric element is formed of lead zirconate titanate (PZT).

11. The piezoelectric actuator of claim 1 wherein the element is polarised in the direction of a longitudinal axis of the body of the element.

12. The piezoelectric actuator of claim 1 wherein the element is actuatable by inducing lateral and/or longitudinal vibration of the element:
lateral vibration being induced by applying an alternating current (AC) signal across a pair of opposing sideface electrodes, whereby—
one sideface electrode is connected to a positive polarity AC signal, while the other is grounded, or
one sideface electrode is connected to a positive polarity AC signal, while the other is connected to a negative polarity AC signal, such that the two signals are 180 degrees out of phase; and
longitudinal vibration being induced by applying an AC signal to either of the pairs of opposing sideface electrodes, or both, whereby the chosen electrodes are connected to the same polarity AC signal, such that they are in phase, whilst at least one of the end electrodes is electrically grounded.

13. The piezoelectric actuator of claim 12 wherein the alternating current signal is a sinusoidal AC signal, a square-wave AC signal and/or a saw-tooth AC signal.

14. The piezoelectric actuator of claim 1 wherein the rotor element or slider element of the actuator is mounted at one end of the piezoelectric element.

15. The piezoelectric actuator of claim 1 wherein three-DOF rotation of the rotor element is obtainable by:
inducing rotation about the x-axis by coupling the lateral y-direction vibration mode with the longitudinal z-direction vibration mode with a 90 degree phase difference;
inducing rotation about the y-axis by coupling the lateral x-direction vibration mode with the longitudinal z-direction vibration mode with a 90 degree phase difference; and
inducing rotation about the z-axis by coupling the lateral x-direction vibration mode with the lateral y-direction vibration mode with a 90 degree phase difference.

16. The piezoelectric actuator of claim 1 further comprising a transducer element mounted at one end of the piezoelectric element and being mounted between the piezoelectric element and the rotor element or slider element.

17. The piezoelectric actuator of claim 16 wherein slots are provided in the transducer element.

18. The piezoelectric actuator of claim 17 wherein the slots are provided in a wall or walls of the transducer element.

19. The piezoelectric actuator of claim 18 wherein the slots are provided in an outer wall(s) and/or inner wall(s) of the piezoelectric element.

20. The piezoelectric actuator of claim 17 wherein slots are arranged in pairs, whereby the slots of a given pair are located on opposing sides of the transducer element and have the same size, shape and/or depth.

21. The piezoelectric actuator of claim 20 wherein each slot of a respective pair of slots is located at or about 180 degrees of rotation angle from the other, about a longitudinal axis of the transducer element.

22. The piezoelectric actuator of claim 20 wherein pairs of slots are positioned symmetrically on the transducer element.

23. The piezoelectric actuator of claim 22 wherein the slots are provided such that the transducer element is symmetrical about two mutually perpendicular planes, wherein the line of intersection of said planes coincides with the longitudinal axis of the transducer element.

24. The piezoelectric actuator of claim 17 wherein the transducer element is hollow or solid, and further wherein when the transducer element is hollow the slots penetrate partially or fully through the wall(s) of the transducer element.

25. The piezoelectric actuator of claim 16 wherein the transducer element is constructed from a low acoustic-dissipative material.

26. The piezoelectric actuator of claim 1 further comprising an isolation structure.

27. The piezoelectric actuator of claim 26 wherein the isolation structure is positioned between the piezoelectric element and a mounting.

28. The piezoelectric actuator of claim 27 wherein the isolation structure comprises a body consisting of a plurality of segments.

29. The piezoelectric actuator of claim 28 wherein the isolation structure comprises a two-segment structure, a greater than two segment structure and/or a periodic structure.

30. The piezoelectric actuator of claim 28 wherein the plurality of segments comprises one or more relatively high rigidity segments and one or more relatively low rigidity segments.

31. The piezoelectric actuator of claim 28 wherein the body of the isolation structure is hollow or solid, and further wherein slots are arranged in a wall or walls of the body of the isolation structure.

32. The piezoelectric actuator of claim 31 wherein the body of the isolation structure comprises a hollow tube.

33. The piezoelectric actuator of claim 32 wherein the slots penetrate partially or fully through the wall(s) of the isolation structure.

34. The piezoelectric actuator of claim 28 wherein the segments of the isolation structure are cylindrical, with the cylindrical axis aligned with the longitudinal axis of the actuator.

35. The piezoelectric actuator of claim 31 wherein the slots are arranged in pairs, whereby the slots of a given pair are located on opposing sides of the segment and have the same size, shape and/or depth.

36. The piezoelectric actuator of claim 35 wherein each slot of a respective pair of slots is located at or about 180 degrees of rotation angle from the other, about a longitudinal axis of the isolation structure.

37. The piezoelectric actuator of claim 35 wherein pairs of slots are positioned symmetrically on the isolation structure.

38. The piezoelectric actuator of claim 37 wherein the slots are arranged in pairs such that the isolation structure is symmetrical about two mutually perpendicular planes, wherein the line of intersection of said planes coincides with the longitudinal axis of the isolation structure.

39. The piezoelectric actuator of claim 37 wherein the longitudinal axis of the isolation structure provides a z-axis, and the slots are provided such that the isolation structure is symmetrical about the y-z plane and the x-z plane.

40. A transducer element for use in a piezoelectric actuator, the transducer element comprising a body having one or more walls, wherein slots are provided in and/or raised portions regions are provided on the wall(s) of the transducer element and arranged in pairs, whereby the slots or raised portion regions of a given pair are located on opposing sides of the transducer element.

41. The transducer element of claim 40 wherein each slot of a respective pair of slots or each raised portion region of a respective pair of raised portion regions is located at or about 180 degrees of rotation angle from the other, about a longitudinal axis of the transducer element.

42. The transducer element of claim 40 wherein the slots and/or raised portion regions are symmetrically arranged on the body.

43. A transducer element for use in a piezoelectric actuator, the transducer element comprising a body having one or more walls, wherein slots are provided in and/or raised portion regions are provided on the wall(s) of the transducer element and arranged such that the transducer element is symmetrical about two mutually perpendicular planes, wherein the line of intersection of said planes coincides with the longitudinal axis of the transducer element.

44. An isolation structure for use in a piezoelectric actuator, the isolation structure comprising a body consisting of a plurality of segments, said segments including one or more relatively low rigidity segments and one or more relatively high rigidity segments, with the difference in rigidity being provided by differences in material properties between the relatively low rigidity and relatively high rigidity segments and/or by their geometric structures.

45. The isolation structure of claim 44 wherein the structure comprises a two-segment or greater segment structure, with the difference in rigidity being provided by differences in their geometric structures, wherein one or more symmetrically arranged pairs of slots are provided in said relatively low rigidity segment(s).

46. The isolation structure of claim 45 wherein the slots of a given pair are located on opposing sides of the relatively low rigidity segment(s) and have the same size, shape and/or depth.

47. The isolation structure of claim 45 wherein each slot of a respective pair of slots is located at or about 180 degrees of rotation angle from the other, about a longitudinal axis of the isolation structure.

48. The isolation structure of claim 45 wherein the slots are arranged in the relatively low rigidity segment(s) such that said segment(s) are symmetrical about two mutually perpendicular planes, wherein the line of intersection of said planes coincides with the longitudinal axis of said segment(s).
